(19) United States
(12) Patent Application Publication
(10) Pub. No.: US 2025/0327848 A1
(43) Pub. Date: Oct. 23, 2025

(54) APPARATUS AND METHOD FOR DETECTING FAULTS IN ELECTRIC GRID

(71) Applicant: Safegrid Oy, Espoo (FI)

(72) Inventor: Tapio MÄNTYSALO, Hevonpää (FI)

(73) Assignee: Safegrid Oy, Espoo (FI)

(21) Appl. No.: 18/870,009

(22) PCT Filed: May 7, 2024
(86) PCT No.: PCT/FI2024/050216

§ 371 Date: Nov. 27, 2024

(30) Foreign Application Priority Data
May 9, 2023 (FI) 20235515

(51) Int. Cl. G01R 31/08; G01R 31/52; G01R 31/58

(52) U.S. Cl. CPC G01R 31/086; G01R 31/52; G01R 31/58

(57) ABSTRACT

A system and a method for locating faults in an electric grid. The system includes a network management module to receive information about physical topology of the electric grid and define a network topology as a block grid with known dimensions based thereon. Two or more traveling wave fault recording units installed at predefined locations in the block grid are employed to detect and record the arrival time of traveling waves generated by a fault, which traverse through neutral wires, ground wires, or cables. The system includes a processing module to determine fault location based on the recorded arrival times from the traveling wave fault recording units and their predefined location coordinates in the block grid, using arithmetic and/or heuristic techniques.

### TECHNICAL FIELD

The present disclosure relates to a system for locating faults in an electric grid. Moreover, the present disclosure relates to a method for locating faults in an electric grid.

### BACKGROUND

An electric grid is a critical infrastructure that requires continuous monitoring and maintenance to ensure the reliable delivery of power.

Generally, an electric grid comprises power lines, power poles, transformers, switching circuits, protection circuits, and so forth. Such an electric grid may be prone to faults occurring due to lighting, wind, trees falling on lines, apparatus failure, and the like. As an example, the fault may cause over current, under voltage, unbalancing of the three phases, high voltage surges, and the like. These faults may cause deviations in voltage values and current values from their nominal ranges in the electric grids. Examples of the faults include but are not limited to, transient faults, ground faults, ground faults, arcing faults, short circuit faults, open circuit faults, overload faults, broken conductors, lost phases, and partial discharges. Most of the faults in the electric grid are transient in nature. For example, a transient fault may occur due to a tree contact, for example, trees falling onto overhead lines, incautious excavation performed nearby underground cables, a bird or an animal contact, a lightning strike, a clash of conductors due to an external force (such as high wind speed), cracks or impurities in insulation material, and the like. The management of the electric grid includes accurately detecting faults and errors in the electric grid and/or the electrical components operating therein. However, such an operation is highly complex and cumbersome.

Ground faults and short circuits in the electric grid are normally managed by splitting feeders into sections. When there is detected a fault in a feeder section, the faulty feeder section is de-energized. The measured fault current may give an indication of the possible fault locations, because topology of the electric grid line, as well as cable impedances and transformer characteristics therein are known. However, especially, phase-to-earth fault currents depend mostly on the earthing impedance of the fault, which may vary hugely. Also, in dense, multi-branched urban networks there can be tens of alternative solutions for the potential fault location when impedance-based fault locationing is used.

Traditional methods involve sectionalizing the electric grid so that there are multiple protection devices, in which protection settings are always more sensitive towards the ends of the lines and branches. Therefore, when these protection devices trip a circuit breaker open, and de-energize the line, if it is found that the fault has disappeared when opening the circuit breaker, then the fault may be localized to that area. However, with such traditional methods, some types of faults, especially infrequent but repeating faults, may be really difficult to detect and properly locate, and the involved process of opening the circuit breakers may bother the utility company and its customers for a long time, due to occasional delivery outages. Moreover, even more problems will be encountered in locating the faults if the network of the electric grid is run in loops (as a grid), instead of tree-like branch structure (aka radials). In such a case, it may not even be possible to find out which route fault signal has taken, and thus may not be possible to locate the fault.

Therefore, in light of the foregoing discussion, there exists a need to overcome the aforementioned limitations/drawbacks.

### SUMMARY

The aim of the present disclosure is to provide a system and a method using traveling wave fault signals that can “jump” over open switches and gaps, traveling through neutral or ground wires of various voltage levels.

The aim of the present disclosure is achieved by a system and a method for locating faults in an electric grid as defined in the appended independent claims to which reference is made to. Advantageous features are set out in the appended dependent claims.

Throughout the description and claims of this specification, the words “comprise”, “include”, “have”, and “contain” and variations of these words, for example “comprising” and “comprises”, mean “including but not limited to”, and do not exclude other components, items, integers or steps not explicitly disclosed also to be present. Moreover, the singular encompasses the plural unless the context otherwise requires. In particular, where the indefinite article is used, the specification is to be understood as contemplating plurality as well as singularity, unless the context requires otherwise.

### BRIEF DESCRIPTION OF THE DRAWINGS

FIG. 1 is an illustration of a schematic block diagram of a system for locating faults in an electric grid, in accordance with one or more embodiments of the present disclosure;

FIG. 2 is an illustration of an exemplary depiction of a network topology of the electric grid represented as a block grid;

FIG. 3 is an illustration of an exemplary depiction of a network topology of the electric grid represented as a block grid for implementing arithmetic techniques for locating faults therein, in accordance with one or more embodiments of the present disclosure;

FIG. 4 is an illustration of an exemplary depiction of a network topology of the electric grid represented as a block grid for implementing heuristic techniques for locating faults therein, in accordance with one or more embodiments of the present disclosure;

FIG. 5 is an illustration of an exemplary depiction of a network topology of the electric grid represented as a block grid considering gaps in physical topology thereof, in accordance with one or more embodiments of the present disclosure;

FIG. 6 is an illustration of a flowchart listing steps involved in a method for locating faults in an electric grid, in accordance with one or more embodiments of the present disclosure;

FIG. 7A is an exemplary depiction of a geographic map of an urban area with a network topology of the electric grid represented as a block grid;

FIG. 7B is an exemplary depiction of a geographic map of an urban area with a network topology of the electric grid represented as a block grid;

FIG. 7C is an exemplary depiction of the geographic map of an urban area as in FIG. 7A with traveling wave signal paths from a fault location and the calculated fault location in a theoretical case where the traveling wave signals would only follow the medium voltage grid topology;

FIG. 7D is another exemplary depiction of the geographic map of an urban area as in FIG. 7A with traveling wave signal paths from a fault location when the traveling wave signals ‘jump’ over open switches and gaps using neutral and ground wiring paths;

FIG. 8A is an illustration of fault location calculation based on arithmetic technique within the geographic urban area map as depicted in FIG. 7A;

FIG. 8B is another illustration of fault location calculation based on arithmetic technique within the geographic urban area map as depicted in FIG. 7A; and

FIG. 8C is yet another illustration of fault location calculation based on arithmetic technique within the geographic urban area map as depicted in FIG. 7A.

### DETAILED DESCRIPTION OF EMBODIMENTS

The following detailed description illustrates embodiments of the present disclosure and ways in which they can be implemented. Although some modes of carrying out the present disclosure have been disclosed, those skilled in the art would recognize that other embodiments for carrying out or practicing the present disclosure are also possible.

In a first aspect, the present disclosure provides a system for locating faults in an electric grid, the system comprising:
a network management module configured to:
   receive information about a physical topology of a region corresponding to the electric grid; and
   define a network topology of the electric grid as a block grid complementary thereto with known dimensions, based on the information about the physical topology of the region corresponding to the electric grid;
two or more traveling wave fault recording units installed at predefined location coordinates in the block grid, and configured to detect and record an arrival time of traveling waves generated by a fault in the electric grid which traverse through one or more of: neutral wire(s), ground wire(s), cable(s) in the region corresponding to the electric grid; and
a processing module configured to:
   receive information about the recorded arrival time of the detected traveling waves from the two or more traveling wave fault recording units and the predefined location coordinates thereof in the block grid; and
   determine a location of the fault in the block grid based on the information about the recorded arrival time of the detected traveling waves from the two or more traveling wave fault recording units and the predefined location coordinates thereof in the block grid by implementing arithmetic and/or heuristic techniques,
   wherein in case of implementing the arithmetic techniques, the processing module is further configured to:
   calculate relative direct distances from each traveling wave fault recording unit of at least one pair of the two or more traveling wave fault recording units to the location of the fault, based on time differences between the recorded arrival times of the detected traveling waves for each traveling wave fault recording unit of the at least one pair of the two or more traveling wave fault recording units; and
   determine the location of the fault based on the calculated relative direct distances and the known dimensions of the block grid; and
   wherein in case of implementing the heuristics techniques, the processing module is further configured to:
   calculate relative line distances from each traveling wave fault recording unit of multiple pairs of the two or more traveling wave fault recording units to the location of the fault, based on time differences between the recorded arrival times of the detected traveling waves for each traveling wave fault recording unit of the multiple pairs of the two or more traveling wave fault recording units; and
   determine the location of the fault based on the calculated relative line distances and the known dimensions of the block grid.

In the present system, by defining the network topology of the electric grid as a block grid complementary to the physical topology and utilizing traveling wave fault recording units to detect fault-generated traveling waves, the system may provide accurate fault location estimates, even in complex electrical grids. The network management module simplifies the network topology, making it easier for the processing module to analyse the grid and locate faults. Installing two or more traveling wave fault recording units at predefined locations within the block grid allows for better coverage and increased accuracy in detecting traveling wave fault signals. The processing module may determine the fault location using arithmetic and/or heuristic techniques, enhancing the overall accuracy and flexibility of the system in adapting to different grid configurations and fault conditions.

In a second aspect, the present disclosure provides a method for locating faults in an electric grid, the method comprising:
receiving information about a physical topology of a region corresponding to the electric grid;
defining a network topology of the electric grid as a block grid complementary thereto with known dimensions, based on the information about the physical topology of the region corresponding to the electric grid;
detecting and recording an arrival time of traveling waves generated by a fault in the electric grid which traverse through one or more of: neutral wire(s), ground wire(s), cable(s) in the region corresponding to the electric grid by configuring two or more traveling wave fault recording units installed at predefined location coordinates in the block grid therefor; and
determining a location of the fault in the block grid based on the information about the recorded arrival time of the detected traveling waves from the two or more traveling wave fault recording units and the predefined location coordinates thereof in the block grid by implementing arithmetic and/or heuristic techniques,
   wherein in case of implementing the arithmetic techniques, the method further comprises:
   calculating relative direct distances from each traveling wave fault recording unit of at least one pair of the two or more traveling wave fault recording units to the location of the fault, based on time differences between the recorded arrival times of the detected traveling waves for each traveling wave fault recording unit of the at least one pair of the two or more traveling wave fault recording units; and
determining the location of the fault based on the calculated relative direct distances and the known dimensions of the block grid; and
   wherein in case of implementing the heuristics techniques, the method further comprises:
      calculating relative line distances from each traveling wave fault recording unit of multiple pairs of the two or more traveling wave fault recording units to the location of the fault, based on time differences between the recorded arrival times of the detected traveling waves for each traveling wave fault recording unit of the multiple pairs of the two or more traveling wave fault recording units; and
      determining the location of the fault based on the calculated relative line distances and the known dimensions of the block grid.

In the present method, the advantages of improved fault location accuracy, real-time fault detection and response, and flexibility in estimation techniques are achieved. By defining the network topology as a block grid complementary to the physical topology and utilizing multiple traveling wave fault recording units to detect and record fault-generated traveling waves, the present method enables accurate and real-time fault detection. The present method's ability to determine the fault location using arithmetic and/or heuristic techniques provides flexibility in adapting to different grid configurations and fault conditions. These features synergistically work together, enabling a comprehensive and efficient approach to fault location in electric grids, ultimately contributing to reduced downtime and more efficient grid maintenance.

For purposes of the present disclosure, the network management module and the processing module may be integral parts of a processing system, such as a server, associated with a utility company that manages the electric grid. The network management module and the processing module may be implemented as software modules running on the processing system, which may consist of one or more servers, cloud-based infrastructure, or distributed computing resources. The network management module is responsible for overseeing the overall configuration, maintenance, and control of the electric grid. The network management module may interact with various components within the grid, including sensors, switches, transformers, and other devices, and collects data about the grid's current state, including its physical topology, and helps the utility company optimize the grid's performance and efficiency. The processing module, on the other hand, focuses on the analysis and processing of data collected from various sources, including the traveling wave fault recording units. The processing module may be responsible for applying algorithms and techniques to the collected data to extract useful information, such as fault locations or potential grid issues. In some examples, the processing module may also employ advanced analytics, machine learning, or artificial intelligence techniques to improve the accuracy and effectiveness of its analysis.

As used herein, the electric grid is a complex network of interconnected electrical components that generate, transmit, distribute, and manage electricity to serve various consumer needs. The electric grid includes power generation sources such as power plants, substations that step-up or step-down the voltage levels, high-voltage transmission lines that transport electricity over long distances, and medium and low-voltage distribution lines that deliver power to end users. Within the electric grid, electricity is transmitted through a combination of overhead lines, underground cables, and various other equipment. The electric grid is a critical part of modern society, ensuring that electricity is reliably and safely delivered to power homes, businesses, and industries. The efficient operation and maintenance of the electric grid depend on the rapid identification and resolution of faults that may occur due to equipment failure, weather events, or human error.

In an embodiment, the electric grid is an urban electric grid with the one or more of: neutral wire(s), ground wire(s), phase conductor(s), cable(s) in the region corresponding to the electric grid being arranged in a substantially criss-cross manner. Herein, the urban electric grid may include tree-like branches, such as, in a typical small town in the US, with medium voltage distributed as overhead lines along the streets of the town center. In this urban electric grid, the neutral wires, ground wires, and cables corresponding to the electric grid are arranged in a substantially criss-cross manner. The criss-cross pattern of the neutral wires, ground wires, and cables is a result of the need to supply electricity to densely populated urban areas with various types of consumers, such as residential, commercial, and industrial users. In the present disclosure, the high density and criss-cross arrangement of the neutral wires, ground wires, and cables in the urban electric grid are exploited to improve fault location accuracy.

In the present disclosure, the high density and criss-cross arrangement of the neutral wires, ground wires, and cables in the urban electric grid are exploited to improve fault location accuracy. It has been discovered through field trials, the high density of neutral wires, ground wires, and cables in such an urban grid is advantageous for determining fault locations. In particular, in such urban electric grids, the interconnected neutral and ground wires may act as pathways for high-frequency traveling wave fault signals, allowing these signals to bypass open switches or gaps in the network. That is, the traveling wave fault signals may jump over open switches and gaps, and they travel effectively using the neutral or ground wires. This phenomenon transforms the neutral wire and the real earth, dirt, into a “radio signal transmission line,” allowing fault signals to propagate across the network. Furthermore, the neutral or ground wire carrying the traveling wave fault signal may be part of low voltage, medium voltage, or high voltage networks. This feature enables the present system for fault location to be versatile and effective across a wide range of electrical grid configurations.

The physical topology of the region corresponding to the electric grid refers to the spatial arrangement and organization of the various components and infrastructure that make up the electric grid within a specific geographical area. The physical topology of a region may vary significantly depending on factors such as population density, geographical features, the presence of natural resources, and the availability of renewable energy sources. For example, a densely populated urban area would have a more complex physical topology due to the higher density of electrical components and infrastructure, while a rural area might have a simpler and more spread-out topology with longer distances between components.

Specifically, the physical topology of the region corresponding to the electric grid, including the layout of electric lines such as feeder lines, neutral wires, ground wires, and cables, is an intricate arrangement of interconnected components that facilitate the distribution of electricity to consumers. The spatial organization of these components is important for the efficient operation and management of the electric grid. Herein, the feeder lines are the primary distribution lines responsible for delivering power from substations to various distribution points, such as transformers, which further supply electricity to end-users. These feeder lines are usually medium-voltage lines that branch out from substations and may be either overhead lines or underground cables. Neutral wires serve as a return path for electric current in single-phase and three-phase electrical systems and are designed to maintain a balanced voltage across the system and minimize potential voltage differences that may cause electrical hazards. Neutral wires are typically interconnected with ground wires at specific points in the grid to ensure safety and system stability. Ground wires, also known as earth wires, provide a path for fault currents to flow into the earth in case of a short circuit or equipment malfunction, preventing electrical shock and damage to the grid components. Cables, which may be overhead or underground, are insulated conductors used to transmit electricity across the grid. They are designed to handle specific voltage levels and carry power from transmission lines to distribution lines and, ultimately, to the end-users.

The information about the physical topology of the region corresponding to the electric grid may be received, by the network management module, from various sources, depending on the available data sources and communication infrastructure. For instance, Geographic Information Systems (GIS) is a powerful tool for collecting, storing, and analyzing spatial data related to the electric grid. Utility companies often maintain GIS databases that include the location and characteristics of electrical components such as transmission lines, distribution lines, substations, transformers, and other grid infrastructure. Furthermore, utility companies maintain records and documents containing information about the grid's infrastructure, including layout plans, schematics, and equipment specifications. By reviewing these records, the required data about the physical topology of the electric grid in a particular region may be obtained. In other examples, satellite and aerial images may be used to gather information about the physical topology of the electric grid.

In the urban electric grids, the electrical infrastructure tends to be densely arranged, with numerous power lines, neutral wires, ground wires, and cables in close proximity. This characteristic allows for the simplification of the network topology to facilitate more efficient fault detection and location. In such cases, the network topology may be defined as a grid that incorporates all lines of different voltage levels, while also closing all minor gaps. The reasoning behind this simplification lies in the behavior of the traveling wave fault signals. As these signals are known to jump over open switches and gaps, and travel effectively using neutral or ground wires, the dense arrangement of the electrical components in urban grids enables the fault signals to propagate even when there are minor gaps or breaks in the lines.

In the present disclosure, the physical topology is used as the basis for defining the simplified network topology for the electric grid, that allows for more effective fault detection and location within the electric grid. To achieve this, the network management module leverages the information about the physical topology of the region corresponding to the electric grid, which includes the spatial arrangement and organization of various components and infrastructure, as well as geographical features and land use characteristics. Based on the information about the physical topology, the network management module defines the network topology of the electric grid as a block grid complementary to the actual grid layout. Typically, the block grid is assumed to be a square block grid, and the distance between two points in the block grid follows the laws of trigonometry so that the distance is sqrt (a\hat{ }2+b\hat{ }2), where a and b may be North-South and West-East distances. This block grid is an abstraction that simplifies the complex structure of the electric grid by representing it as a grid with known dimensions, where each block corresponds to a specific area within the region. The block grid aims to capture the essential characteristics of the electric grid, such as the arrangement of power lines, neutral wires, ground wires, and cables, while disregarding minor details that may not significantly impact the fault detection and location process. The use of a block grid may result in reduced complexity and computational requirements for the fault detection and location process, while still providing accurate and reliable results.

Term “block” here refers e.g., to a city block, a residential block, i.e., a space or an area surrounded by streets, or to a group of buildings bounded by streets. The block can be further divided into smaller spaces or areas inside each block. Thus, as opposed to a rural area grid, the block grid is considerably tighter in nature as almost all the streets have cables or overhead lines along the street, or alternative traveling wave pathways such as neutral or ground conductors, low-voltage lines, cable TV, traffic light, or street lighting cabling. The rural grids have very infrequent backfeed possibilities, and there are typically few situations where neutral or ground conductors, low-voltage lines, cable TV, traffic light, or street lighting cabling would form an alternative path for traveling wave signals, except at switchgears.

As discussed, the traveling wave signals travel effectively using the neutral wires, ground wires, or cables, turning those into a “radio signal transmission line.” Herein, the neutral wire and the actual earth, or dirt, act as the primary conduits for these signals. Regardless of whether the neutral or ground wire is part of a low-voltage, medium-voltage, or high-voltage network, the traveling wave signals may still propagate effectively. This characteristic is exploited for the detection and recording of the traveling wave signals, as it enables the signals to traverse a wide range of voltage levels within the electric grid.

The use of two or more traveling wave fault recording units installed at predefined location coordinates in the block grid enables for determining location of the fault in the present system. These traveling wave fault recording units are strategically placed, often 0.5 km (kilometer) to 1 km apart in dense urban electric grids, to accurately capture the location and route of the traveling wave fault signals generated by the fault in the electric grid. The traveling wave fault recording units are designed to detect and record the arrival time of these traveling waves as they traverse through neutral wires, ground wires, and cables in the region corresponding to the electric grid. The high-frequency traveling wave signals exhibit unique characteristics that facilitate their detection by the recording units. In present examples, the traveling wave fault recording units may incorporate GPS time synchronization therein to accurately timestamp the detected traveling wave signals. This ensures precise time correlation between the signals received by different traveling wave fault recording units, which is essential for determining the fault location as discussed later in the description. There can be, for example, two, three, four, five, six, seven, eight, nine or more traveling wave fault recording units, installed at predefined location coordinates in the block grid, or in the corresponding dense urban electric grids, or suburban electric grids.

Herein, the processing module is disposed in signal communication with the two or more traveling wave fault recording units to receive information about the recorded arrival time of the detected traveling waves therefrom. This may be achieved through wired or wireless communication methods, such as fibre-optic cables, radiofrequency communication, or cellular networks. Further, the processing module may receive information about the predefined location coordinates of the two or more traveling wave fault recording units in the block grid from the network management module. The processing module, then, processes data from the traveling wave fault recording units, which includes the recorded arrival time of the detected traveling waves as well as the predefined location coordinates of these units within the block grid. The processing module integrates the recorded arrival time data from multiple traveling wave fault recording units while taking into account the predefined location coordinates of these traveling wave fault recording units within the block grid to triangulate the position of the fault within the electric grid. In some examples, the processing module may also consider other factors, such as the physical topology of the electric grid or the characteristics of the traveling wave signals, to further refine the fault location estimation. This comprehensive approach enables the processing module to deliver reliable and accurate fault location information, which is crucial for the effective management and maintenance of the electric grid. For instance, this information is vital for utility companies to swiftly identify, assess, and address issues within the electric grid, ultimately ensuring its reliable and efficient operation. In an embodiment, the two or more traveling wave fault recording units are configured to detect the traveling waves which traverse through the one or more of: neutral wire(s), ground wire(s), cable(s) by jumping over open switches or gaps in the region corresponding to the electric grid. It may be understood that when a fault occurs in the electric grid, it generates high frequency traveling wave signals. These signals may “jump” over open switches or gaps, not by physically passing over them, but by traveling through alternative pathways, such as neutral wires that are common to high-voltage, medium-voltage, and low-voltage lines and cables, or inductive, or capacitive coupling between the two lines. Consequently, even in the presence of gaps or breaks in the electrical infrastructure, the traveling wave fault signals continue to propagate throughout the electric grid. This unique characteristic of traveling wave signals allows them to bypass conventional network topology constraints and reach the traveling wave fault recording units. The traveling wave fault recording units are designed to capture and analyze the high-frequency signals, enabling them to distinguish the traveling wave fault signals from other types of signals or noise present in the electric grid.

In present examples, the traveling wave fault recording units may be equipped with advanced sensing technology to accurately detect these traveling waves as they traverse through the various conducting pathways. Suitable sensors may include voltage sensors or Rogowski coils, which may effectively capture high-frequency signals in the presence of low-frequency power signals. Further, the traveling wave fault recording units may be installed at strategic locations within the urban electrical grid, ensuring they are in close proximity to the neutral or ground wires of the different voltage levels. The traveling wave fault recording units may be positioned such that they may capture the traveling wave fault signals even if they jump over open switches or gaps.

Further, the traveling wave fault recording units may be equipped with filtering capabilities to isolate high-frequency traveling wave signals from other background signals or noise in the neutral or ground wires, such as by employing bandpass filters tuned to the frequency range of interest which may help in isolating the traveling wave signals.

In case of implementing the arithmetic techniques, the processing module is further configured to:
calculate relative direct distances from each traveling wave fault recording unit of at least one pair of the two or more traveling wave fault recording units to the location of the fault, based on time differences between the recorded arrival times of the detected traveling waves for each traveling wave fault recording unit of the at least one pair of the two or more traveling wave fault recording units; and
determine the location of the fault based on the calculated relative direct distances and the known dimensions of the block grid.

When implementing the arithmetic techniques, the processing module is configured to carry out a series of calculations to determine the location of the fault in the electric grid. Firstly, using the recorded arrival times of the detected traveling waves from at least one pair of the two or more traveling wave fault recording units, the processing module calculates the time differences between the arrival times for each unit of the pair. With these time differences, the processing module computes the relative direct distances from each traveling wave fault recording unit of the pair to the location of the fault. These distances may be derived based on the known speed of traveling waves and the time differences between the recorded arrival times for each recording unit of the pair. Finally, the processing module determines the location of the fault within the block grid by utilizing the calculated relative direct distances and the known dimensions of the block grid. This may be done using various techniques, such as triangulation or trilateration, which involve the intersection of multiple lines or circles, respectively, drawn from the predefined location coordinates of the traveling wave fault recording units. By incorporating arithmetic techniques, the processing module may systematically and precisely calculate the location of the fault within the block grid.

For instance, assuming a fault occurs at a specific location within the electric grid, the traveling wave fault recording units A, B, C, and D, whose exact location coordinates within the block grid are already known, all detect and record the arrival time of the traveling wave fault signals generated by the fault. These traveling wave fault recording units accurately timestamp the detected traveling wave fault signals, for example, by utilizing GPS time synchronization. The recorded arrival time information is then provided to the processing module; which upon receiving the timestamp and location information from the traveling wave fault recording units A, B, C, and D, determines the fault location by applying arithmetic techniques. The processing module calculates the relative direct distances between the fault location and each of the recording units based on the differences in the recorded arrival times. By combining this distance information with the known dimensions of the block grid and the location coordinates of the traveling wave fault recording units, the processing module is able to accurately resolve the fault location within the electric grid.

In case of implementing the heuristics techniques, the processing module is further configured to:
calculate relative line distances from each traveling wave fault recording unit of multiple pairs of the two or more traveling wave fault recording units to the location of the fault, based on time differences between the recorded arrival times of the detected traveling waves for each traveling wave fault recording unit of the multiple pairs of the two or more traveling wave fault recording units; and
determine the location of the fault based on the calculated relative line distances and the known dimensions of the block grid.

When implementing the heuristic techniques, the processing module is configured to perform a series of steps that utilize a more intuitive approach to determining the fault location within the electric grid. Herein, the processing module calculates the time differences between the recorded arrival times of the detected traveling waves for each traveling wave fault recording unit of multiple pairs of the two or more traveling wave fault recording units. Using these time differences, the processing module computes the relative line distances from each traveling wave fault recording unit of the multiple pairs to the location of the fault. These line distances may be calculated considering the known speed of traveling waves and the time differences between the recorded arrival times for each recording unit of the multiple pairs. The processing module then determines the location of the fault within the block grid by analyzing the calculated relative line distances and the known dimensions of the block grid. This may be achieved using heuristic methods that consider various combinations of line distances and block grid dimensions to generate a set of potential fault locations. The processing module may then select the most plausible fault location from this set based on additional criteria, such as the consistency of the results or the presence of physical barriers in the grid. By employing heuristic techniques, the processing module may effectively estimate the fault location within the electric grid using a more flexible and adaptable approach. This methodology is particularly useful in scenarios where the grid's complexity or incomplete information may hinder the application of more rigid arithmetic techniques. The heuristic approach allows the processing module to incorporate multiple factors and weigh them against each other to generate a reliable fault location estimate, ultimately helping utility companies to address issues in the electric grid more efficiently and effectively.

For instance, in an exemplary 6×6 block grid complementary to the electric grid, and with the traveling wave fault recording units A, B, C and D being positioned at four corners of the said block grid with ‘A’ at bottom-right, ‘B’ at bottom-left, ‘C’ at top-left and ‘D’ at top-right, for a fault occurring at (4.5, 4) from a top corner, the traveling wave would traverse 6.5 length units to reach the traveling wave fault recording unit ‘B’ and 3.5 length units to reach the traveling wave fault recording unit ‘A’. The time difference corresponds to a 3-length unit distance, leading to a solution where the fault is 4.5 length units from the traveling wave fault recording unit ‘B’ and 1.5 length units from the traveling wave fault recording unit ‘A’. Similarly, the processing module may process other pairs of the traveling wave fault recording units along the corners of the block grid. For example, for the diagonal pair of the traveling wave fault recording units ‘B’ and ‘D’, the fault signal would travel 6.5 length units to the traveling wave fault recording unit ‘B’ and 5.5 length units to the traveling wave fault recording units ‘D’. In diagonal terms, this corresponds to 6.5/sqrt (2) length units from the traveling wave fault recording unit B and 5.5/sqrt (2) length units from the traveling wave fault recording unit ‘D’. Therefore, the diagonal distance should be 0.707 length units greater from the traveling wave fault recording unit ‘B’ than from the traveling wave fault recording unit ‘A’. These calculations provide six hints for determining the fault location, which may be found mathematically, for instance, by employing triangulation techniques. The processing module, leveraging the heuristic method, utilizes these hints along with the known dimensions of the block grid and the location coordinates of the traveling wave fault recording units to accurately determine location of the fault within the electric grid.

In some examples, the processing module may use a combination of arithmetic and heuristic techniques to improve the accuracy and reliability of the fault location process. For example, it might first apply arithmetic techniques to generate an initial estimate of the fault location, and then use heuristic techniques to refine the estimate based on additional information or contextual factors. This combined approach enables the processing module to leverage the strengths of both techniques, resulting in a more accurate and robust fault location determination.

In an embodiment, the network management module is further configured to:
receive information about the physical topology including details about sections within which traversal of the traveling waves through the one or more of: neutral wire(s), ground wire(s), cable(s) is not feasible; and
define the network topology to include gaps corresponding to the said sections; and
the processing module is further configured to determine the location of the fault in consideration of the network topology with the gaps in the block grid.

Herein, the network management module has an enhanced functionality to better define the network topology by taking into account sections within which traversal of the traveling waves through the neutral wires, ground wires, and cables is not feasible. In this context, the network management module is configured to receive information about the physical topology, which includes details about such sections that may be characterized by obstacles like lakes, parks, or fields that hinder the propagation of traveling waves. Based on the received information about the physical topology and the identified sections, the network management module refines the network topology by incorporating gaps corresponding to these sections. This leads to a more accurate representation of the network topology that acknowledges the limitations in traveling wave propagation due to the presence of these gaps. The processing module is also adapted to take into consideration the refined network topology with gaps when determining the location of the fault in the block grid. By accounting for the network topology with gaps, the processing module may generate a more accurate estimation of the fault location that reflects the actual conditions and constraints present in the electric grid.

This approach ensures that the analysis and calculations take into account the realistic constraints of the grid, such as areas where the traversal of the traveling wave fault signals through neutral wire(s), ground wire(s), or cable(s) is not feasible due to physical barriers or the absence of electrical connections. By incorporating these real gaps into the network topology representation, the processing module may more accurately determine the location of the fault, as it considers the actual conditions and limitations present in the electric grid. This enhanced approach to fault location determination not only improves the accuracy of the fault location estimation but also provides a more comprehensive understanding of the grid's behavior in response to faults. Consequently, this allows utility companies to better plan their maintenance and repair strategies, ensuring more efficient and reliable operation of the electric grid.

In an embodiment, the processing module is further configured to:
receive information about a past determined location of a past fault in the block grid;
receive information about an exact location of the said past fault in the block grid;
compute an adjustment factor based on the past determined location and the exact location of the said past fault in the block grid; and
adjust the determined location of the fault in the block grid based on the adjustment factor.

That is, the processing module may receive information about a previously determined location of the past fault within the block grid, which was calculated using the same methodology as the current fault location. Further, the processing module may obtain information about the exact location of the said past fault in the block grid, which may have been determined through field inspections or other means of accurate location identification. The processing module may then compute the adjustment factor based on a comparison between the past determined location and the exact location of the said past fault within the block grid. This adjustment factor represents the difference between the calculated fault location and the actual fault location, accounting for any discrepancies in the methodology or grid properties. The processing module may then apply the adjustment factor to the currently determined location of the fault within the block grid, resulting in an adjusted fault location that takes into consideration the past performance of the system. This adjustment enhances the accuracy of the fault location by incorporating historical data and refining the calculation based on past experiences, thus improving the overall performance of the fault detection and location in the system.

For instance, to enhance accuracy due to imperfect grid geometry, the system may adapt and learn from past faults when the exact fault locations are validated by utility personnel. For example, traveling wave fault location methods assume a certain velocity for the traveling wave signal, typically ranging from 0.9 to 0.99 times the speed of light in overhead lines and approximately 0.5 times the speed of light in cables. By adjusting the signal velocity parameter and/or the geometric distance between the validated fault location and the sensor locations, the system may improve the accuracy of subsequent fault location calculations in the vicinity of the same area. This adaptive learning approach takes into account the actual grid conditions and specific characteristics, allowing the system to refine its calculations and provide more precise fault location estimates in the future.

The present disclosure also relates to the method as described above. Various embodiments and variants disclosed above, with respect to the aforementioned system, apply mutatis mutandis to the method.

In an embodiment, the method further comprises detecting the traveling waves which traverse through one or more of: neutral wire(s), ground wire(s), conductor(s), cable(s) by jumping over open switches or gaps in the region corresponding to the electric grid by configuring the two or more traveling wave fault recording units therefor.

In case of implementing the arithmetic techniques, the method further comprises:
calculating relative direct distances from each traveling wave fault recording unit of at least one pair of the two or more traveling wave fault recording units to the location of the fault, based on time differences between the recorded arrival times of the detected traveling waves for each traveling wave fault recording unit of the at least one pair of the two or more traveling wave fault recording units; and
determining the location of the fault based on the calculated relative direct distances and the known dimensions of the block grid.

In case of implementing the heuristics techniques, the method further comprises:
calculating relative line distances from each traveling wave fault recording unit of multiple pairs of the two or more traveling wave fault recording units to the location of the fault, based on time differences between the recorded arrival times of the detected traveling waves for each traveling wave fault recording unit of the multiple pairs of the two or more traveling wave fault recording units; and
determining the location of the fault based on the calculated relative line distances and the known dimensions of the block grid.

In an embodiment, the method further comprises:
receiving information about the physical topology including details about sections within which traversal of the traveling waves through the one or more of: neutral wire(s), ground wire(s), cable(s) is not feasible;
defining the network topology to include gaps corresponding to the said sections; and
determining the location of the fault in consideration of the network topology with the gaps in the block grid.

In an embodiment, the method further comprises:
receiving information about the physical topology including details about sections within which traversal of the traveling waves through the one or more of: neutral wire(s), ground wire(s), cable(s) is not feasible;
defining the network topology to include gaps corresponding to the said sections; and
determining the location of the fault in consideration of the network topology with the gaps in the block grid.

In an embodiment, the electric grid is an urban electric grid with the one or more of: neutral wire(s), ground wire(s), phase conductor(s), cable(s) in the region corresponding to the electric grid being arranged in a substantially criss-cross manner.

The system and the method of the present disclosure are capable of accurately detecting faults and their locations in the electric grid, even in cases where the fault current is compensated by an arc suppression coil or other grounding impedance. The present disclosure by incorporating the current sensing unit enhances fault detection accuracy for both short circuits and earth/ground faults by working in conjunction with the traveling wave fault recording units. The present disclosure leverages the traveling wave fault recording units, which incorporates fault indicators (sensors) on at least one, and possibly all, outgoing feeders. When a fault occurs, it is detected between at least two sensors placed along the feeder line. Multiple sensors may be necessary for each feeder to ensure comprehensive coverage, and these sensors are typically situated several kilometers away from the substation. Such inclusion of additional high-frequency sensors at strategic locations within the substation improves the performance and reliability of the traveling wave fault positioning system by increasing its sensitivity to fault-induced transient signals, which ultimately leads to more accurate detection and localization of faults within the electrical grid.

In an urban electrical grid with tree-like branches, such as a typical small town in the US, in which medium voltage is distributed as overhead lines along the streets of the town center, spanning an area of, for example, about 0.5 km×0.5 km, to locate faults with approximately one block accuracy, ten or more traveling wave sensors may be required. The system and the method of the present disclosure offers several advantages, particularly for dense urban or suburban electric grids. By utilizing neutral or ground wires connected across low, mid, and high voltage lines, and interconnected cable shields, the present system and method may bypass the need for detailed switching information in the network topology. The presence of neutral/ground wires alongside overhead lines further enhances the accuracy and effectiveness of fault location. The present system and method also allow for accurate fault location with a relatively small number of traveling wave fault location units compared to conventional installations that strictly follow network topology and switching state. Additionally, the present system and method take into account large gaps in the grid, preventing short signal paths between two traveling wave fault location units from traveling over those gaps. This results in a more accurate and efficient determination of fault location for complex electric grids, such as urban electric grids.

### DETAILED DESCRIPTION OF THE DRAWINGS

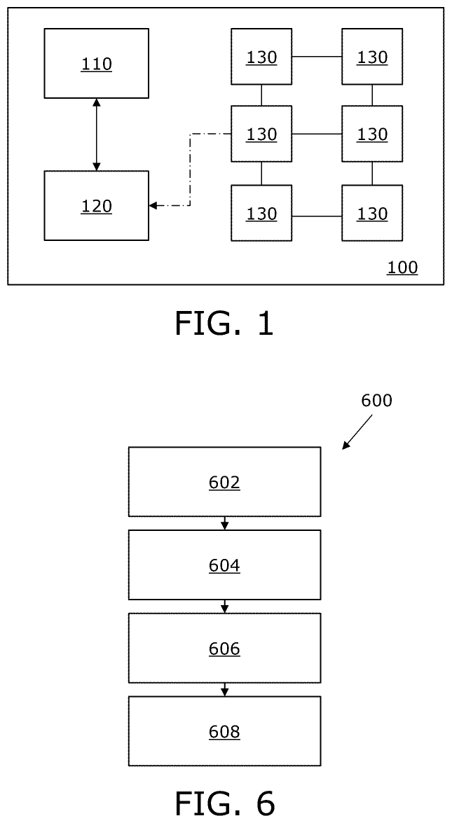

Referring to FIG. 1, illustrated is a schematic block diagram of a system (as represented by reference numeral 100) for locating faults in an electric grid, in accordance with one or more embodiments of the present disclosure. The system 100 includes a network management module 110 configured to receive information about a physical topology of a region corresponding to the electric grid; and define a network topology of the electric grid as a block grid complementary thereto with known dimensions, based on the information about the physical topology of the region corresponding to the electric grid. The system 100 also includes two or more traveling wave fault recording units 130 installed at predefined location coordinates in the block grid and configured to detect and record an arrival time of traveling waves generated by a fault in the electric grid which traverse through one or more of: neutral wire(s), ground wire(s), cable(s) in the region corresponding to the electric grid. The system 100 further includes a processing module 120 configured to receive information about the recorded arrival time of the detected traveling waves from the two or more traveling wave fault recording units and the predefined location coordinates thereof in the block grid; and determine a location of the fault in the block grid based on the information about the recorded arrival time of the detected traveling waves from the two or more traveling wave fault recording units and the predefined location coordinates thereof in the block grid by implementing arithmetic and/or heuristic techniques.

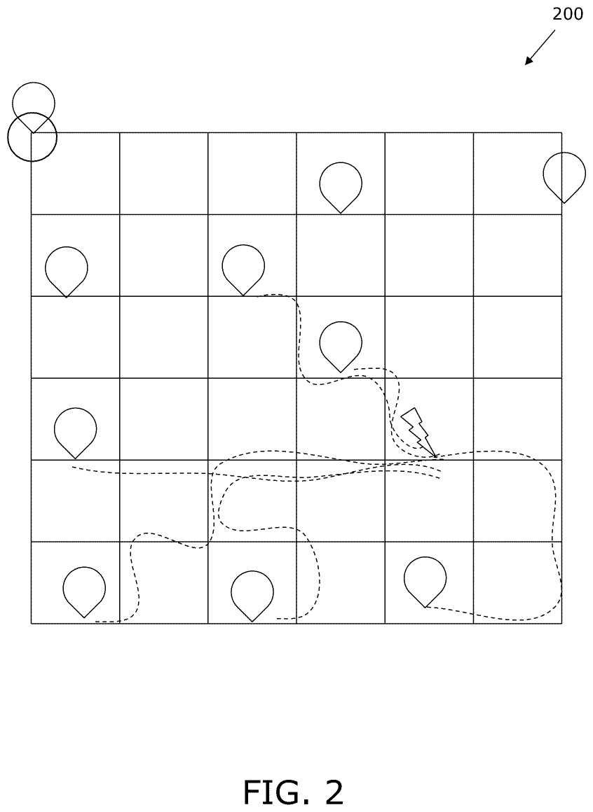

Referring to FIG. 2, illustrated is an exemplary depiction of a network topology of the electric grid represented as a block grid 200. The block grid 200 may be representative of an urban electrical grid with tree-like branches, such as those found in typical small towns, medium voltage is often distributed as overhead lines along the streets of the town center, with a substation (represented as a circle) at a top-left corner thereof. To locate faults (an example of fault location is represented by a lightning bolt in FIG. 2) with approximately one block accuracy in a 0.5 km×0.5 km area, around ten traveling wave sensors (represented as pins) may be needed as illustrated.

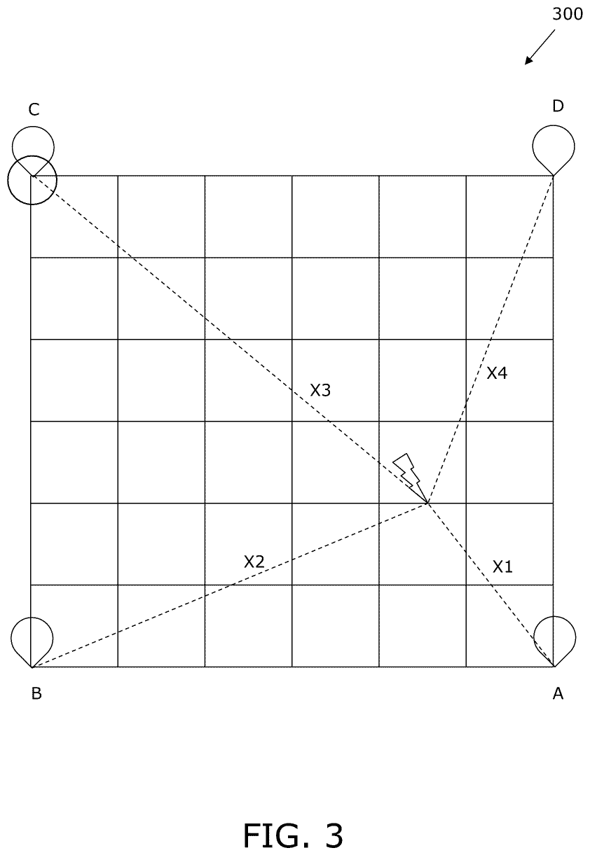

Referring to FIG. 3, illustrated is an exemplary depiction of a network topology of the electric grid represented as a block grid 300, in accordance with one or more embodiments of the present disclosure.

Herein, the block grid 300 has a substation (represented as a circle) at a top-left corner thereof. The block grid 300 also has two or more traveling wave fault recording units (such as, the traveling wave fault recording units 130), four shown as A, B, C and D, disposed at four corners thereof. By employing the block grid 300, using arithmetic techniques, the processing module (such as, the processing module 120) is configured to calculate relative direct distances ‘X1-X4’ from each traveling wave fault recording unit ‘A-D’ within at least one pair of units to the fault location (as represented by a lightning bolt). This calculation is based on the time differences between the recorded arrival times of detected traveling waves for each unit within the pair. Once these relative direct distances ‘X1-X4’ are calculated, the processing module may determine the fault location by considering both the calculated relative direct distances ‘X1-X4’ and the known dimensions of the block grid 300.

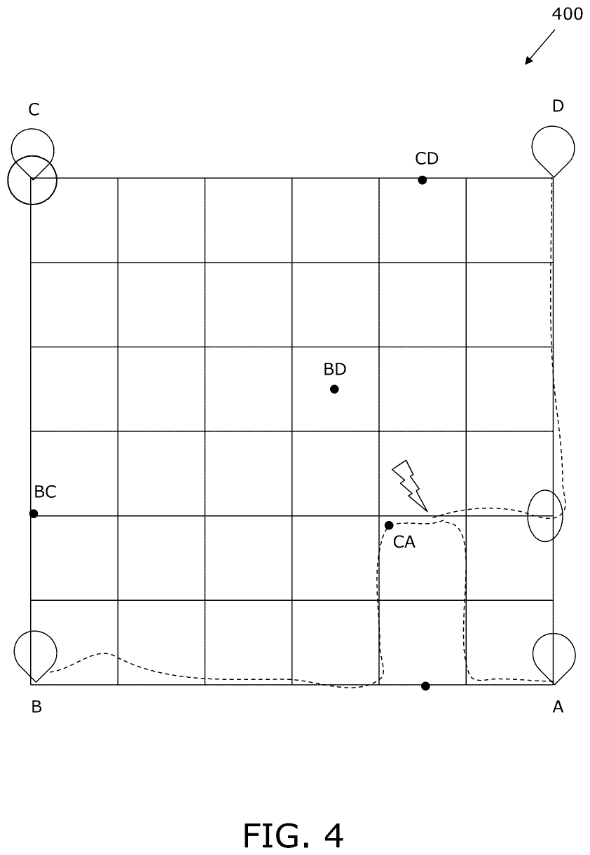

Referring to FIG. 4, illustrated is an exemplary depiction of a network topology of the electric grid represented as a block grid 400, in accordance with one or more embodiments of the present disclosure. Herein, the block grid 400 has a substation (represented as a circle) at a top-left corner thereof. The block grid 400 also has two or more traveling wave fault recording units (such as, the traveling wave fault recording units 130), four shown as A, B, C and D, disposed at four corners thereof.

By employing the block grid 400, using heuristic techniques, the processing module (such as, the processing module 120) is configured to calculate relative line distances from each traveling wave fault recording unit ‘A-D’ to the fault location (as represented by a lightning bolt). This is based on the time differences between the recorded arrival times of detected traveling waves for each unit in the multiple pairs (A-D). For instance, with a 3 length unit time difference between signals received by units ‘A’ and ‘B’, the fault location is determined as 4.5 length units from ‘B’ and 1.5 length units from ‘A’. Similarly, other device pairs along the edges are processed. Using diagonal device pairs, such as ‘BD’, ‘BC’, ‘CA’ and ‘CD’, the processing module calculates the fault location based on the difference in the diagonal distances. This process generates multiple hints for fault location, which may then be found mathematically, such as through triangulation, resulting in an accurate fault location determination.

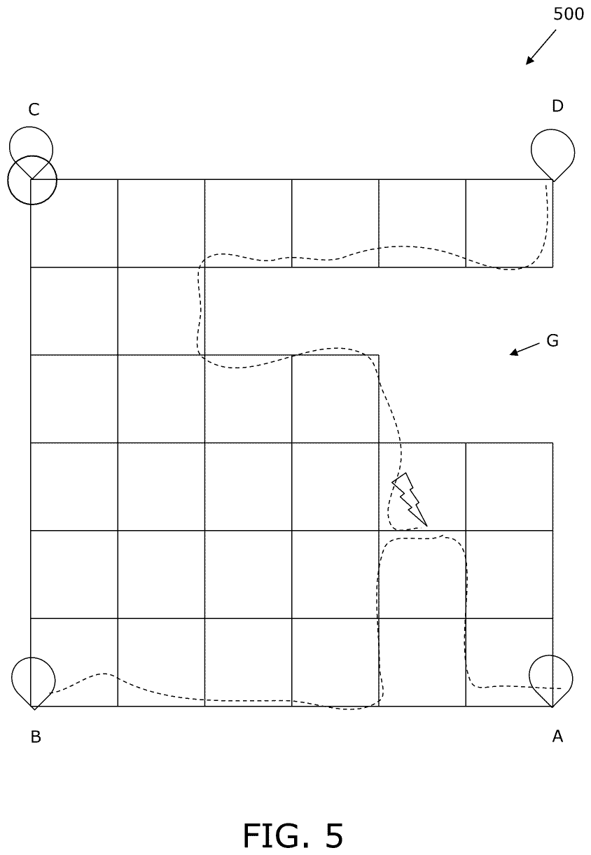

Referring to FIG. 5, illustrated is an exemplary depiction of a network topology of the electric grid represented as a block grid 500, in accordance with one or more embodiments of the present disclosure. Herein, the block grid 500 has a substation (represented as a circle) at a top-left corner thereof. The block grid 500 also has two or more traveling wave fault recording units (such as, the traveling wave fault recording units 130), four shown as A, B, C and D, disposed at four corners thereof. For generating such block grid 500, the network management module (such as, the network management module 110) is configured to receive information about the physical topology of the electric grid, including details about sections where traveling waves cannot traverse through neutral wires, ground wires, or cables. Based on this information, the network management module defines the network topology to include gaps (such as gap ‘G’, as shown) that correspond to these sections. The processing module (such as, the processing module 120) then takes into account the network topology with these gaps when determining the location of a fault (such as, a fault represented as a lightning bolt) in the block grid 500. This comprehensive approach ensures a more accurate fault location by considering the limitations and restrictions of the physical topology of the electric grid.

Referring to FIG. 6, illustrated is a flowchart listing steps involved in a method 600 for locating faults in an electric grid, in accordance with an embodiment of the present disclosure. At step 602, method 600 includes receiving information about a physical topology of a region corresponding to the electric grid. At step 604, the method 600 includes defining a network topology of the electric grid as a block grid complementary thereto with known dimensions, based on the information about the physical topology of the region corresponding to the electric grid. At step 606, the method 600 includes detecting and recording an arrival time of traveling waves generated by a fault in the electric grid which traverse through one or more of: neutral wire(s), ground wire(s), cable(s) in the region corresponding to the electric grid by configuring two or more traveling wave fault recording units installed at predefined location coordinates in the block grid therefor. At step 608, the method 600 includes determining a location of the fault in the block grid based on the information about the recorded arrival time of the detected traveling waves from the two or more traveling wave fault recording units and the predefined location coordinates thereof in the block grid by implementing arithmetic and/or heuristic techniques. It may be appreciated that the above steps are only illustrative and other alternatives can also be provided where one or more steps are added, one or more steps are removed, or one or more steps are provided in a different sequence without departing from the spirit and the scope of the present disclosure.

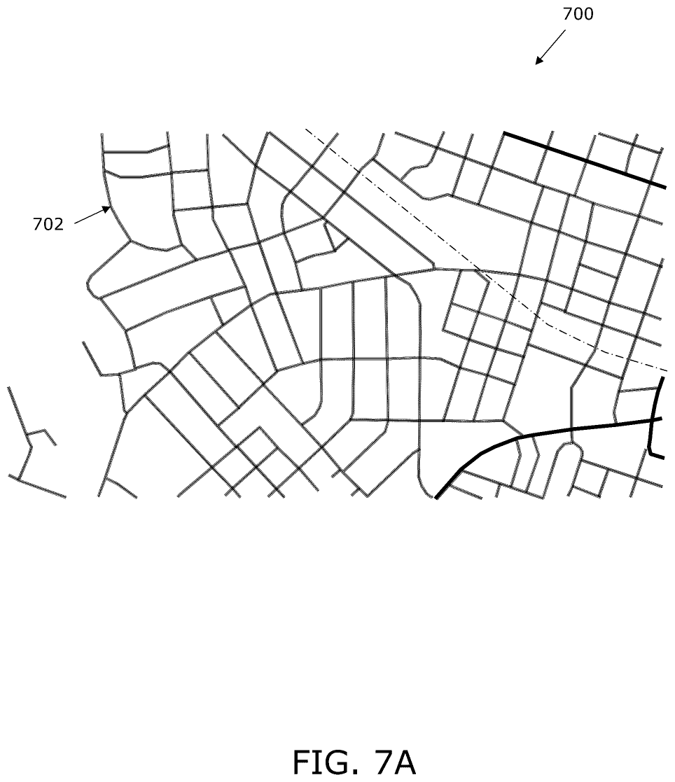

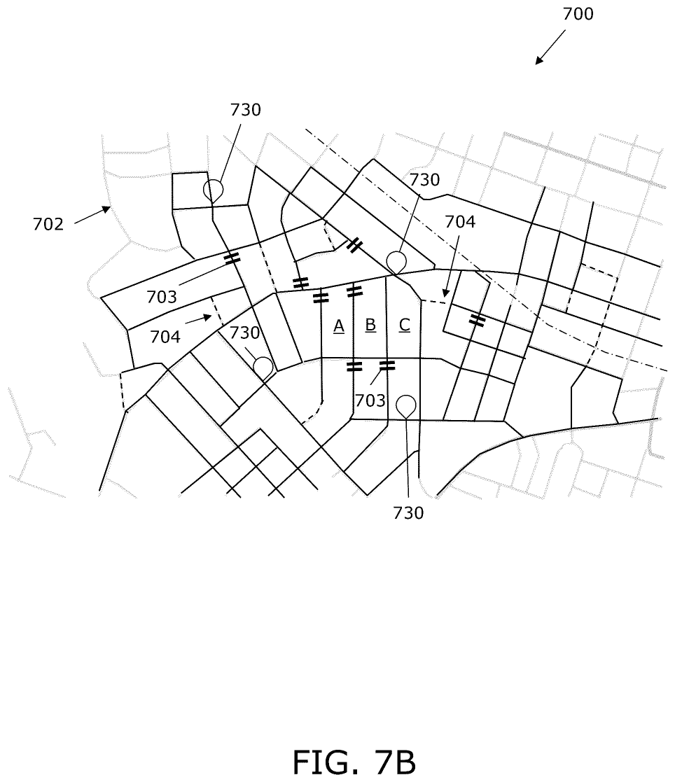

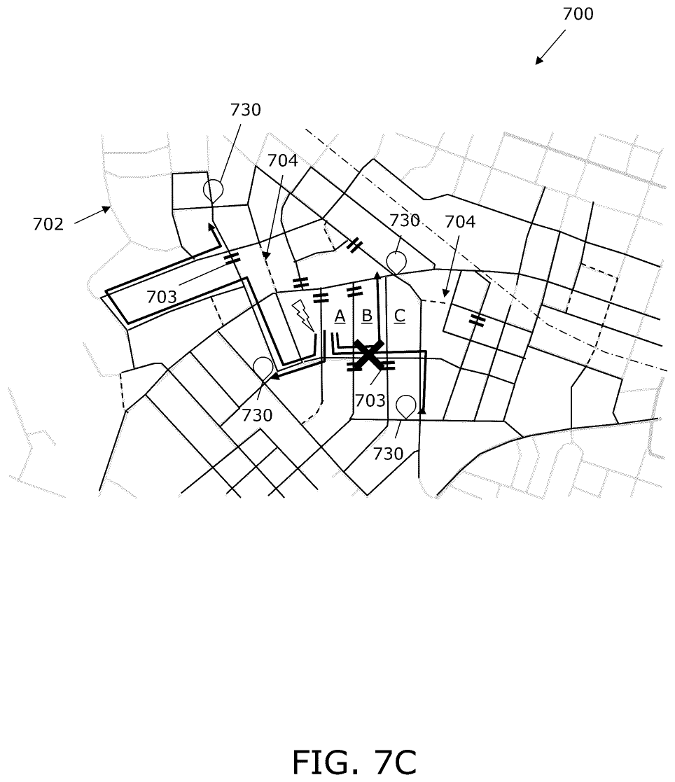

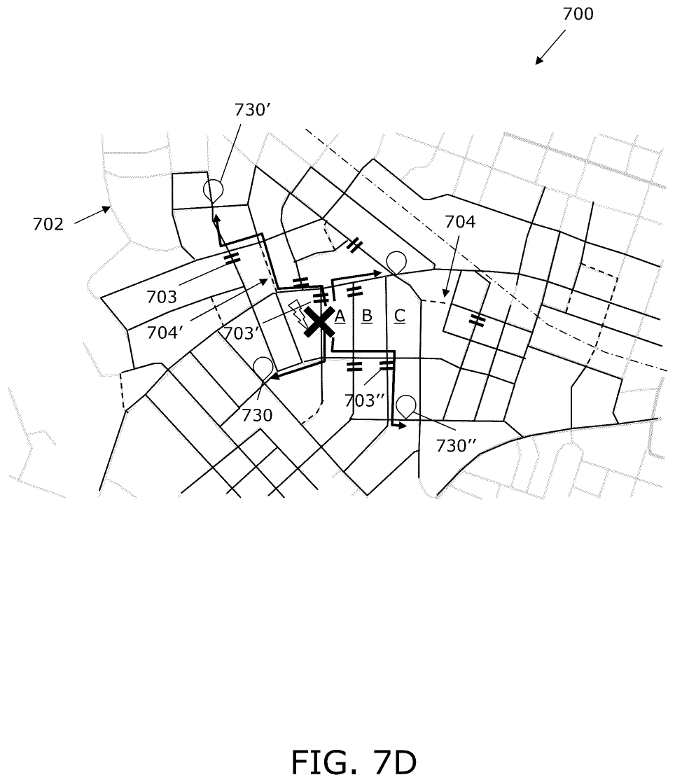

Referring to FIGS. 7A and 7B, illustrated is a geographic map of an urban area with a network topology of the electric grid represented as a block grid. The urban area typically contains blocks and streets 702, and each block in the urban area may be at least partially surrounded or bounded by one or more streets. The streets 702 (see FIG. 7A) may have (underground) cables or overhead lines along the streets, or alternative traveling wave pathways, such as neutral or ground conductors, low-voltage lines, cable TV, traffic light, or street lighting cabling.

Referring to FIG. 7B, the block grid 700 comprises a plurality of blocks, denoted here as A, B, and C. The block grid may further contain other blocks in addition to blocks A, B, and C. For example, the blocks that are surrounding the blocks A, B, and C. Each block can be a group of one or buildings surrounded by streets. The electric grid comprises an electric power source (not shown in FIG. 7B) supplying electricity to various end users, for example buildings in the blocks. The electric grid further comprises a branched network of power lines, including underground cables and/or overhead power lines (denoted as solid black lines, in FIG. 7B), and neutral or ground wire(s), or conductors 704 (denoted as dashed line, in FIG. 7B) connected to the electric power source, through which power lines the electricity is supplied to the end users, and a plurality of potentially open switches 703, such as circuit breakers, blade switches, or dead-end insulators with bypass arrangements, arranged in a branched network of the power lines. The network of the power lines has line sections, of which at least some are divided by the plurality of switches 703, and arranged in the power lines, e.g., between the blocks, and/or along the streets 702, that supply electricity to those power line sections. The electric grid also has one or more traveling wave recording units 730 (of which four are shown in FIG. 7B) which are installed at predefined location coordinates in the block grid 700. The one or more traveling wave recording units 730 are configured to detect and record an arrival time of traveling waves generated by a fault in the electric grid which traverse through one or more of: neutral wire(s), ground wire(s), one or more phase conductors, cable(s) in the region corresponding to the electric grid.

Referring to FIG. 7C, illustrated is the geographic urban area map as depicted in FIG. 7A with an example of traveling wave signal paths from a fault location. Assuming a fault happens in the location indicated by a lightning bolt (see FIG. 7C), and the plurality of switches 703 are all open (i.e. the switch has shut off the electric power from the line section), the traveling wave recording units 730, whose exact locations are already known, all receive the traveling wave fault signal, which travels along the pathways (denoted as thick solid black lines, in FIG. 7C), timestamp the signals accurately, for example, using GPS time, provide the signals to a central processing unit, which, upon receiving the signals, then resolves the fault location by combining timestamp and distance information received, by implementing arithmetic and/or heuristics techniques. In this case of FIG. 7C, using heuristics technique, when the switches 703 are open, the traveling wave signals are perceived to be received by one or more traveling wave recording units 730 through one or more phase conductors, and following the distribution (medium voltage) grid topology only, i.e., the assumption is that the signals do not pass over open switches 703 and paths without medium voltage conductors 704. The fault location resulting is not accurate or reliable, as different sensor pairs provide conflicting information.

Referring to FIG. 7D, illustrated is the geographic urban area map as depicted in FIG. 7A with another example of traveling wave signal paths from fault location. A fault happens in the location indicated by a lightning bolt (see FIG. 7D), the traveling wave recording units 730 then receive the traveling wave signal fault signal through alternative pathways if compared to a scenario of FIG. 7C, as the assumption of the fault location method now is that the traveling wave signals “jump” over open switches, dead end insulators, etc. using neutral, ground, or low voltage signal paths. Here, the fault signal travels to the traveling wave recording unit 730′ along path 704′, i.e., through a low voltage line of the electric grid and via a possibly open switch. In this case, the traveling wave signals “jump” over open switches and gaps using neutral and ground wiring paths. Whereas the fault signal received by the traveling wave recording unit 730″ travels through one or more phase conductors. Thus, the fault location resulting from heuristic calculations using the real traveling wave signal paths instead of only the medium voltage topology map, in the cases described above is potentially located at different coordinates, and more accurately and reliably by the method 7D. Utilizing the alternative signal paths (neutral and ground wires, low voltage cabling) to medium voltage conductors generally requires increased signal sensitivity and noise suppression. Fault locations are exemplarily marked with “X” in FIGS. 7C and 7D.

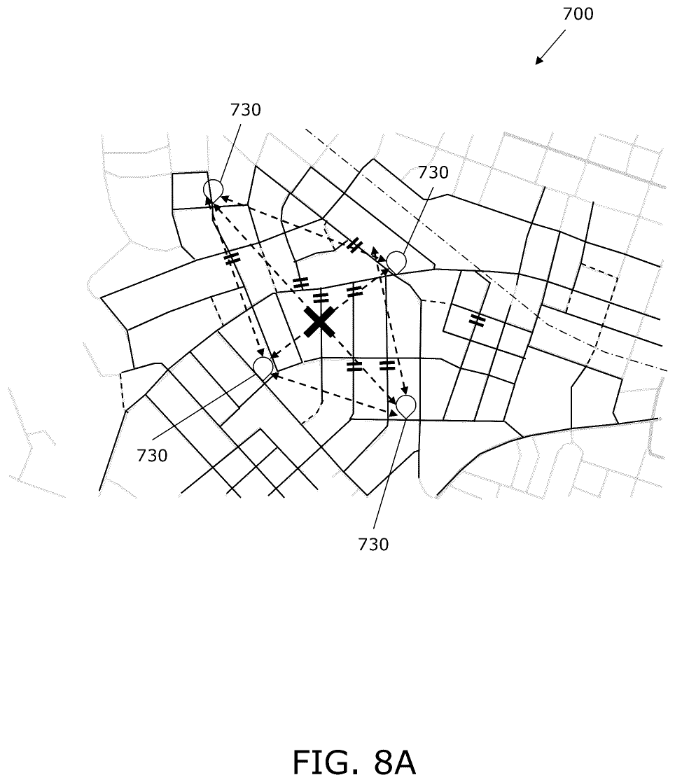

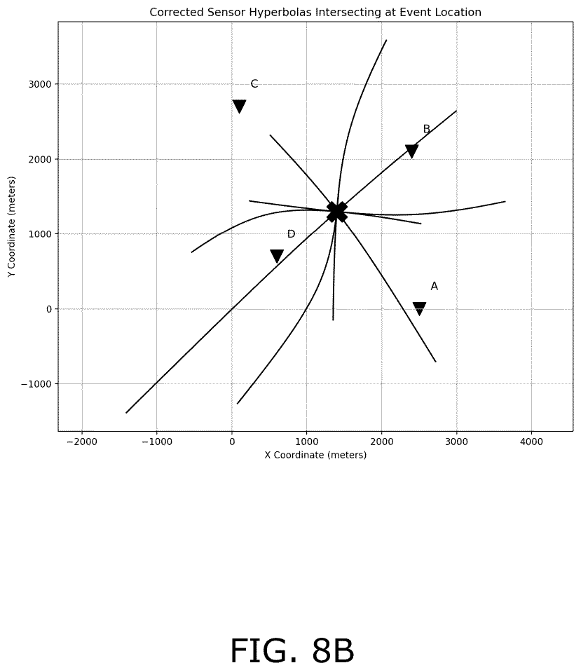

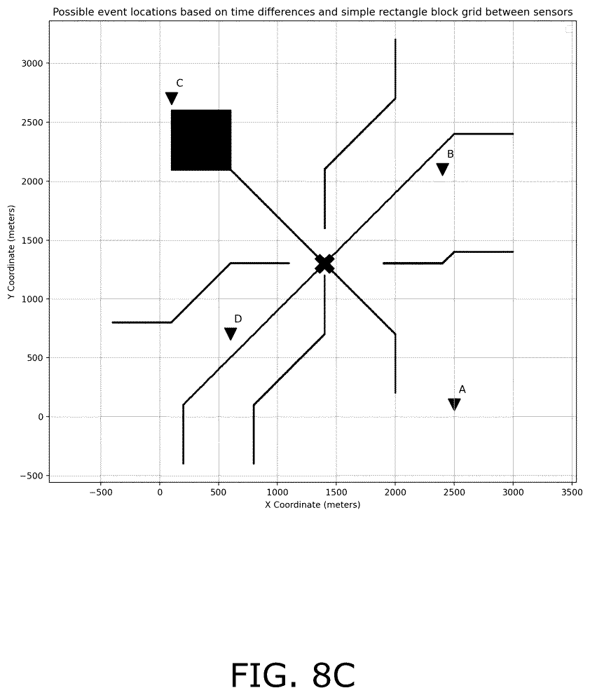

Referring to FIG. 8A, as the sensor locations are known, and with the knowledge that in the area limited by the sensors picking up the traveling wave signals, there is a tight grid of traveling wave signal paths, it is possible to locate the fault accurately without the exact knowledge of the grid topology map, and without dense coverage of sensors. Two examples of these arithmetic methods are described in FIG. 8B and FIG. 8C.

Referring to FIG. 8B, depicted is fault location calculation based on purely arithmetic technique without the detailed knowledge of the geographic urban area map as depicted in FIG. 7A. The potential fault locations calculated by sensor pairs using arrival time differences of the traveling waves form hyperbolas, as the traveling waves are (by the method) assumed to travel using direct flight paths from the event location to the sensors. The multiple hyperbolas intersect at a small area, and this can be then pointed to as the potential fault location. FIG. 8B shows corrected sensor hyperbolas intersecting at event locations. The x-axis is the x-coordinate in meters and the y-axis is the y-coordinate in meters.

Referring to FIG. 8C, depicted is fault location calculation based on purely arithmetic technique without the detailed knowledge of within the geographic urban area map as depicted in FIG. 7A, but instead of assuming direct flight paths between the event location and the sensors, a block grid path (e.g., the signal can only travel vertical or horizontal lines) is utilized. A block grid path essentially is 1.41 times longer when the event location is diagonal (45 degrees) in relation to the sensor but equals the direct flight path in case the event location is map horizontal or map vertical in relation to the sensor. The potential fault locations calculated by sensor pairs using arrival time differences of the traveling waves form lines or areas, which fulfill the traveling wave signal arrival time difference equation. Multiple lines or areas of potential fault location intersect on a small area, and this can be then pointed to as the potential fault location. FIG. 8C shows the possible event locations based on time differences and simple rectangle block grid between the sensors. The x-axis is the x-coordinate in meters and the y-axis is the y-coordinate in meters.

1. A system for locating faults in an electric grid, the system comprising:
a network management module configured to:
receive information about a physical topology of a region corresponding to the electric grid,
wherein the network management module is further configured to:
define a network topology of the electric grid as a block grid complementary thereto, by representing the network topology of electric grid as a grid with known dimensions, based on the information about the physical topology of the region corresponding to the electric grid, where each block corresponds to a specific area within the region corresponding to the electric grid;
two or more traveling wave fault recording units installed at predefined location coordinates in the block grid, and configured to detect and record an arrival time of traveling waves generated by a fault in the electric grid which traverse through one or more of: neutral wire(s), ground wire(s), cable(s) in the region corresponding to the electric grid; and
a processing module configured to:
receive information about the recorded arrival time of the detected traveling waves from the two or more traveling wave fault recording units and the predefined location coordinates thereof in the block grid; and
determine a location of the fault in the block grid based on the information about the recorded arrival time of the detected traveling waves from the two or more traveling wave fault recording units and the predefined location coordinates thereof in the block grid by implementing arithmetic and/or heuristic techniques,
wherein in case of implementing the arithmetic techniques, the processing module is further configured to:
calculate relative direct distances from each traveling wave fault recording unit of at least one pair of the two or more traveling wave fault recording units to the location of the fault, based on time differences between the recorded arrival times of the detected traveling waves for each traveling wave fault recording unit of the at least one pair of the two or more traveling wave fault recording units; and
determine the location of the fault based on the calculated relative direct distances and the known dimensions of the block grid; and
wherein in case of implementing the heuristics techniques, the processing module is further configured to:
calculate relative line distances from each traveling wave fault recording unit of multiple pairs of the two or more traveling wave fault recording units to the location of the fault, based on time differences between the recorded arrival times of the detected traveling waves for each traveling wave fault recording unit of the multiple pairs of the two or more traveling wave fault recording units; and
determine the location of the fault based on the calculated relative line distances and the known dimensions of the block grid.

2. A system according to claim 1, wherein the two or more traveling wave fault recording units are configured to detect the traveling waves which traverse through the one or more of: neutral wire(s), ground wire(s), cable(s), by jumping over open switches or gaps in the region corresponding to the electric grid.

3. A system according to claim 1, wherein:
the network management module is further configured to:
receive information about the physical topology including details about sections within which traversal of the traveling waves through the one or more of: neutral wire(s), ground wire(s), cable(s) is not feasible; and
define the network topology to include gaps corresponding to the said sections; and
the processing module is further configured to determine the location of the fault in consideration of the network topology with the gaps in the block grid.

4. A system according to claim 1, wherein the processing module is further configured to:
receive information about a past determined location of a past fault in the block grid;
receive information about an exact location of the said past fault in the block grid;
compute an adjustment factor based on the past determined location and the exact location of the said past fault in the block grid; and
adjust the determined location of the fault in the block grid-based on the adjustment factor.

5. A system according to claim 1, wherein the electric grid is an urban electric grid with the one or more of: neutral wire(s), ground wire(s), cable(s) in the region corresponding to the electric grid being arranged in a substantially criss-cross manner.

6. A method for locating faults in an electric grid, the method comprising:
receiving information about a physical topology of a region corresponding to the electric grid,
wherein the method further comprises:
defining a network topology of the electric grid as a block grid complementary thereto, by representing the network topology of electric grid as a grid with known dimensions, based on the information about the physical topology of the region corresponding to the electric grid, where each block corresponds to a specific area within the region corresponding to the electric grid;
detecting and recording an arrival time of traveling waves generated by a fault in the electric grid which traverse through one or more of: neutral wire(s), ground wire(s), cable(s) in the region corresponding to the electric grid by configuring two or more traveling wave fault recording units installed at predefined location coordinates in the block grid therefor; and
determining a location of the fault in the block grid based on the information about the recorded arrival time of the detected traveling waves from the two or more traveling wave fault recording units and the predefined location coordinates thereof in the block grid by implementing arithmetic and/or heuristic techniques,
wherein in case of implementing the arithmetic techniques, the method further comprises:
calculating relative direct distances from each traveling wave fault recording unit of at least one pair of the two or more traveling wave fault recording units to the location of the fault, based on time differences between the recorded arrival times of the detected traveling waves for each traveling wave fault recording unit of the at least one pair of the two or more traveling wave fault recording units; and
determining the location of the fault based on the calculated relative direct distances and the known dimensions of the block grid; and
wherein in case of implementing the heuristics techniques, the method further comprises:
calculating relative line distances from each traveling wave fault recording unit of multiple pairs of the two or more traveling wave fault recording units to the location of the fault, based on time differences between the recorded arrival times of the detected traveling waves for each traveling wave fault recording unit of the multiple pairs of the two or more traveling wave fault recording units; and
determining the location of the fault based on the calculated relative line distances and the known dimensions of the block grid.

7. A method according to claim 6, further comprising detecting the traveling waves which traverse through one or more of: neutral wire(s), ground wire(s), cable(s), by jumping over open switches or gaps in the region corresponding to the electric grid by configuring the two or more traveling wave fault recording units therefor.

8. A method according to claim 6, further comprising:
receiving information about the physical topology including details about sections within which traversal of the traveling waves through the one or more of: neutral wire(s), ground wire(s), cable(s) is not feasible;
defining the network topology to include gaps corresponding to the said sections; and
determining the location of the fault in consideration of the network topology with the gaps in the block grid.

9. A method according to claim 6, further comprising:
receiving information about a past determined location of a past fault in the block grid;
receiving information about an exact location of the said past fault in the block grid;
computing an adjustment factor based on the past determined location and the exact location of the said past fault in the block grid; and
adjusting the determined location of the fault in the block grid-based on the adjustment factor.

10. A method according to claim 6, wherein the electric grid is an urban electric grid with the one or more of: neutral wire(s), ground wire(s), cable(s) in the region corresponding to the electric grid being arranged in a substantially criss-cross manner.
